(19) United States
(12) Patent Application Publication
(10) Pub. No.: US 2014/0028158 A1
(43) Pub. Date: Jan. 30, 2014

(54) PIEZOELECTRIC VIBRATING STRIP, PIEZOELECTRIC VIBRATOR, OSCILLATOR, ELECTRONIC DEVICE, AND RADIO TIMEPIECE

(71) Applicant: Seiko Instruments Inc., Chiba (JP)

(72) Inventor: Daishi ARIMATSU, Chiba (JP)

(73) Assignee: Seiko Instruments Inc., Chiba (JP)

(21) Appl. No.: 13/950,541

(22) Filed: Jul. 25, 2013

(30) Foreign Application Priority Data
Jul. 26, 2012 (JP) JP2012166156

(51) Int. Cl. H01L 41/04

(52) U.S. Cl. CPC H01L 41/04
USPC 310/370

(57) ABSTRACT

A piezoelectric vibrating strip, a piezoelectric vibrator, an oscillator, an electronic device, and a radio timepiece, in which the CI value can be reduced further while preventing a vibrating arm portion from vibrating in a second warp mode. The piezoelectric vibrating strip includes a plurality of parallel vibrating arm portions in a width direction, a base portion couples base ends of the vibrating arm portions, and a groove portion resides in at least one of a main face and a back face of the vibrating arm portion and extends from proximate the base end toward a free end of the vibrating arm portion. A break portion divides the groove portion and suppresses warp deformation of the vibrating arm portion in a second warp mode between a vibrating node portion of the vibrating arm portion proximate the base end and a vibrating node portion proximate the free end.

### RELATED APPLICATIONS

This application claims priority under 35 U.S.C. §119 to Japanese Patent Application No. 2012-166156 filed on Jul. 26, 2012, the entire content of which is hereby incorporated by reference.

### BACKGROUND OF THE INVENTION

1. Field of the Invention

The present invention relates to a piezoelectric vibrating strip, a piezoelectric vibrator, an oscillator, an electronic device, and a radio timepiece.

2. Background Art

A cellular phone and a portable information terminal device has a piezoelectric vibrator using a crystal or the like as a time source, a timing source for a control signal, a reference signal source and the like. Various piezoelectric vibrators of this type have been provided, and among them, a known piezoelectric vibrator includes a piezoelectric vibrating strip of a tuning fork type housed in a package.

FIG. 20 is a plan view showing a conventional piezoelectric vibrating strip.

As shown in FIG. 20, a piezoelectric vibrating strip 2001 of the tuning fork type is a crystal strip of thin plate shape having a pair of vibrating arm portions 2010 and 2011 placed side by side in a width direction, and a base portion 2020 coupling base ends of the pair of vibrating arm portions 2010 and 2011 in a length direction. An exciting electrode 2030 for vibrating the pair of vibrating arm portions 2010 and 2011 is formed on the outer face of each of the vibrating arm portions 2010 and 2011.

FIG. 21 and FIG. 22 are explanatory diagrams showing the behavior of the piezoelectric vibrating strip.

As shown in FIGS. 21 and 22, when a voltage is applied to the exciting electrode 2030 formed on the vibrating arm portion 2010, the piezoelectric vibrating strip 2001 vibrates in a predetermined direction at a predetermined resonance frequency such that the leading ends of the pair of vibrating arm portions 2010 and 2011 are brought closer to and away from each other. A vibration mode in which each of the vibrating arm portions 2010 and 2011 warps and vibrates such that the leading ends of the pair of vibrating arm portions 2010 and 2011 are brought closer to and away from each other as shown is referred to as a warp vibration mode. In the warp vibration mode, the leading ends of the vibrating arm portions serve as free ends. The warp vibration mode includes not only a “fundamental mode” in which vibrations occur at the fundamental frequency but also a “harmonic mode” in which vibrations occur at a harmonic frequency such as a second warp mode and a third warp mode. For example, the vibration mode shown in FIG. 21 is the “fundamental mode,” and the vibration mode shown in FIG. 22 is the “harmonic mode (second warp mode).” In the “harmonic mode,” vibrating nodes 2010a and 2011a are formed at the base ends of the vibration arm portions 2010 and 2011, and vibrating nodes 2010b and 2011b are also formed closer to the leading ends. The vibrations occur such that the displacement is at the maximum substantially at the center between the vibrating nodes.

When stable vibrations occur at a desired resonance frequency (for example, 32.768 kHz) in any of the vibration modes, the vibrator can be used as various timing sources. In the harmonic mode, however, the vibrator generally vibrates at a frequency higher than a frequency typically required, and the vibrator is difficult to use as various timing sources. On the other hand, when the vibrator vibrates in the fundamental mode, the desired resonance frequency described above is easily achieved.

In recent years, the devices on which the package is mounted have been reduced in size, and accordingly, a further size reduction is needed for the piezoelectric vibrating strip. For reducing the size of the piezoelectric vibrating strip by reducing the width of the vibrating arm portion, the resulting width of the exciting electrode is reduced to increase the CI (Crystal Impedance) value. To address this, various techniques have been proposed for reducing the size of the piezoelectric vibrating strip while reducing the increase in the CI value. Since the CI value can be denoted as R for the sake of convenience, the following description is made assuming that the CI value in the fundamental mode is R1 and the CI value in the second harmonic mode is R2.

It is known that the piezoelectric vibrating strip is vibrated more efficiently and accurately as the R value becomes lower. Thus, various configurations for reducing the R value have conventionally been known. For example, as shown in FIG. 20, it is known that a groove portion 2040 is formed in a front side portion or a back side portion of the pair of vibrating arm portions 2010 and 2011. Since this configuration can reduce the interval between the exciting electrodes 2030 of different poles, the R value can be reduced. This can suppress the increase in the R value even when the size of the vibrator is reduced, so that the vibrator can be provided with a reduced size and higher performance (see, for example, JP-A-2002-261558).

The related art described above, however, has the following problems.

When a further reduction in the R value is desired for the vibrator having the groove portion formed in the front side portion or the back side portion of the vibrating arm portion, a possible approach is to increase the length of the groove in a longitudinal direction relative to the vibrating arm. For example, it is known that a comparison made between 55% and 60% of the length of the groove in the longitudinal direction relative to the overall length of the vibrating arm shows that the latter achieves a further reduction in the R value. The “length of the vibrating arm” and the “length of the groove” described in the following refer to the length of the arm and the length of the groove in the longitudinal direction, respectively.

The present inventors have found that, if the length of the groove in the longitudinal direction is increased, R1 (R value in the fundamental mode) becomes larger than R2 (R value in the second harmonic) when the length of the groove relative to the length of the vibrating arm exceeds a certain proportion. Since the piezoelectric vibrator vibrates at the second harmonic frequency in this case, the desired resonance frequency can not be provided even at any low R value.

The magnitudes of R1 and R2 are now described. It is known that the piezoelectric vibrating strip having the warp vibration mode generally vibrates in the vibration mode with a lower R value. Specifically, when R1 is lower than R2, the vibrating strip vibrates in the “fundamental mode,” and when R2 is lower than R1, the vibrating strip vibrates in the “harmonic mode.” Thus, R1 needs to be lower than R2 in order to vibrate the vibrating strip in the “fundamental mode.”

Specifically, it is found that, when the length of the groove is increased in order to reduce the R value, both R1 and R2 are reduced but R2 is reduced at a higher rate than that of R1, so that the relationship of R1<R2 is switched to R1>R2.

This is now described in more detail with reference to FIG. 23. FIG. 23 shows a graph showing changes in the R1 value and the R2 value in the related art in which the vertical axis represents the R1 value and the R2 value and the horizontal axis represents TL100/L100. TL100 refers to the length of the groove and L100 refers to the length of the vibrating arm (FIG. 20).

As shown in FIG. 23, as the value of TL100/L100 becomes larger, it can be found that the inclination of the reduction in the R2 value becomes larger than the inclination of the reduction in the R1 value. As a result, the R2 value becomes smaller than the R1 value when the value of TL100/L100 reaches approximately 0.58 as shown in FIG. 23, which causes the problem in which the vibrating arm portion 2010 vibrates in the second warp mode. It should be noted that while the second warp mode is used as an example of the harmonic mode, it has been seen that the R2 value is smaller than R1 value in other harmonic modes such as the third harmonic, the fourth harmonic and the like.

To address this, the present invention has been made in view of the circumstances described above, and it is an object thereof to provide a piezoelectric vibrating strip, a piezoelectric vibrator, an oscillator, an electronic device, and a radio timepiece in which the R1 value can be reduced further while preventing the vibrating arm portion from vibrating in the second warp mode.

### SUMMARY OF THE INVENTION

To solve the problems described above, a piezoelectric vibrating strip according to the present invention includes a base portion and a plurality of parallel vibrating arms in a width direction, the base portion couples base ends of the vibrating arms in a length direction, and a longitudinal groove portion in at least one of a main face and a back face of the vibrating arm extends from proximate the base end toward the free ends of the vibrating arms, and a break portion divides the longitudinal groove portion into a first groove portion and a second groove portion. The break portion suppressing warp deformation of the vibrating arms in a second warp mode between a vibrating node portion of the vibrating arm portion proximate to the base end and a vibrating node portion of the vibrating arm portion proximate to the free end when a vibration mode of the vibrating arm portion is the second warp mode.

Since the break portion is provided at the portion of the vibrating arm portion that is displaced in the second warp mode, the deformation (deformation amount) of the vibrating arm portion is suppressed in the second warp mode. Specifically, the R2 value can be increased. When the R2 value can be increased, the relationship of R1<R2 can be maintained while effectively reducing the R1 value even when the length of the groove is increased relative to the length of the vibrating arm, so that the piezoelectric vibrating strip can be vibrated in the fundamental mode. Specifically, assuming that the length of the vibrating arm is L and the length of the groove is TL1, the relationship of R1<R2 can be maintained when TL1/L≈0.6. It has been found that the relationship of R1<R2 can be maintained even when TL1/L≈0.68.

In the piezoelectric vibrating strip according to the present invention, the break portion is provided near a maximum amplitude portion of the vibrating arm portion when the vibration mode of the vibrating arm portion is the second warp mode.

Since the break portion is provided near the maximum amplitude portion (for example, a “middle” portion of warp deformation), the deformation (deformation amount) of the vibrating arm in the second warp mode can be effectively suppressed to increase the R2 value. Thus, the length of the groove can be increased to reduce the R1 value, and at the same time, the vibration of the vibrating arm portion in the second warp mode can be prevented. In this case, it has been found that the relationship of R1<R2 can be maintained even when the TL1/L≈0.68.

The break portion is a breaking portion which breaks the groove portion in a longitudinal direction of the vibrating arm portion.

With this formation, as compared with the case where the groove portion has a constant width and is not broken in the longitudinal direction, the vibrating arm portion has increased rigidity at the breaking portion. Thus, the breaking portion vibrates “less,” so that the deformation (deformation amount) in the second warp mode can be suppressed. In other words, the vibration of the vibrating arm portion in the second warp mode can be prevented with the simple configuration.

The break portion is a reduced width portion in which a dimension of the groove portion is reduced in the width direction.

With this formation, as compared with the case where the groove portion has a constant width and is formed continuously in the longitudinal direction, the vibrating arm portion has increased rigidity at the reduced width portion. Thus, the reduced width portion vibrates “less,” so that the deformation (deformation amount) in the second warp mode can be suppressed. In other words, the vibration of the vibrating arm portion in the second warp mode can be prevented with the simple configuration.

A recess portion is formed in the breaking portion. The recess portion refers to a circular groove, a reduced width groove, a slit and the like. With this formation, the deformation (deformation amount) in the second warp mode can be suppressed in the recess portion of the breaking portion. In other words, the vibration of the vibrating arm portion in the second warp mode can be prevented with the simple configuration.

In various embodiments, the break portion includes two adjacent recess portions. In one embodiment, a width of the two adjacent recess portions is the same and the width of the two adjacent recess portions is less than one half of a width of each of the first and second groove portions. In another embodiment, a narrow longitudinal groove connects the first groove portion and the second groove portion. In yet another embodiment, the break portion is a narrow rib.

In various embodiments, the vibrating arms include a reduced width portion between the base ends and the free ends and the break portion resides in the reduced width portion.

In an embodiment, the ratio of a combined of the first groove and second groove portions is TL1 and a length from a center of the break portion to the base portion is TL2, is such that TL2/TL1 is about 0.50 to about 0.80.

In an embodiment, a third groove portion in the vibrating arms in proximity to the base ends.

In an embodiment, the base portion includes a first base portion proximate to the base ends of the vibrating arms and a second base portion opposite the vibrating arms, where the first base portion has a smaller width than the second base portion in the lateral width direction.

In various embodiments, the piezoelectric vibrating strip further includes first and second side arms connected to the base portion in the lateral width direction and extending parallel to and on either side of the vibrating arms. In another embodiment first and second indentations reside in opposite sides of the base portion in the lateral width direction.

A piezoelectric vibrator according to the present invention includes the piezoelectric vibrating strip as described above.

This configuration can provide the piezoelectric vibrator capable of preventing the vibration of the vibrating arm portion in the second warp mode while further reducing the R1 value.

An oscillator according to the present invention includes the piezoelectric vibrator described above electrically connected to an integrated circuit as an oscillator.

This configuration can provide the oscillator capable of preventing the vibration of the vibrating arm portion in the second warp mode while further reducing the R1 value.

An electronic device according to the present invention includes the piezoelectric vibrator described above electrically connected to a time measuring section.

This configuration can provide the electronic device capable of preventing the vibration of the vibrating arm portion in the second warp mode while further reducing the R1 value.

A radio timepiece according to the present invention includes the piezoelectric vibrator described above electrically connected to a filter section.

This configuration can provide the radio timepiece capable of preventing the vibration of the vibrating arm portion in the second warp mode while further reducing the R1 value.

According to the present invention, the piezoelectric vibrating strip, the piezoelectric vibrator, the oscillator, the electronic device, and the radio timepiece in which the R1 value can be reduced further while preventing the vibrating arm portion from vibrating in the second warp mode can be provided.

### BRIEF DESCRIPTION OF THE DRAWINGS

FIG. 1 is a perspective view showing the outer appearance of a piezoelectric vibrator in the present embodiment viewed from a lid substrate.

FIG. 2 is a diagram of the internal structure of the piezoelectric vibrator according to a first embodiment of the present invention and shows a piezoelectric vibrating strip viewed from above with the lid substrate removed therefrom.

FIG. 3 is a section view taking along an A-A line in FIG. 2.

FIG. 4 is an exploded perspective view of the piezoelectric vibrator according to the first embodiment of the present invention.

FIG. 5 is a plan view of the piezoelectric vibrating strip according to the first embodiment of the present invention.

FIG. 6A is a section view taken along a B-B line in FIG. 5, and FIG. 6B is a section view taken along a C-C line in FIG. 5.

FIG. 7 is a plan view of a piezoelectric vibrating strip according to a second embodiment of the present invention.

FIGS. 8A to 8C show graphs illustrating changes in an R1 value and an R2 value in the second embodiment of the present invention, in which FIG. 8A shows the case where TL2/TL1 is 0.5, FIG. 8B shows the case where TL2/TL1 is 0.6, and FIG. 8C shows the case where TL2/TL1 is 0.8.

FIG. 9 is a plan view of a piezoelectric vibrating strip according to a third embodiment of the present invention.

FIG. 10 is a plan view of a piezoelectric vibrating strip according to a fourth embodiment of the present invention.

FIG. 11 is a plan view of a piezoelectric vibrating strip according to a fifth embodiment of the present invention.

FIG. 12 is a plan view of a piezoelectric vibrating strip according to a sixth embodiment of the present invention.

FIG. 13 is a plan view of a piezoelectric vibrating strip according to a seventh embodiment of the present invention.

FIG. 14 is a plan view of a piezoelectric vibrating strip according to an eighth embodiment of the present invention.

FIG. 15 is a plan view of a piezoelectric vibrating strip according to a ninth embodiment of the present invention.

FIG. 16 is a plan view of a piezoelectric vibrating strip according to a tenth embodiment of the present invention.

FIG. 17 is a schematic diagram showing an embodiment of an oscillator according to the present invention.

FIG. 18 is a schematic diagram showing an embodiment of an electronic device according to the present invention.

FIG. 19 is a schematic diagram showing an embodiment of a radio timepiece according to the present invention.

FIG. 20 is a plan view showing a conventional piezoelectric vibrating strip.

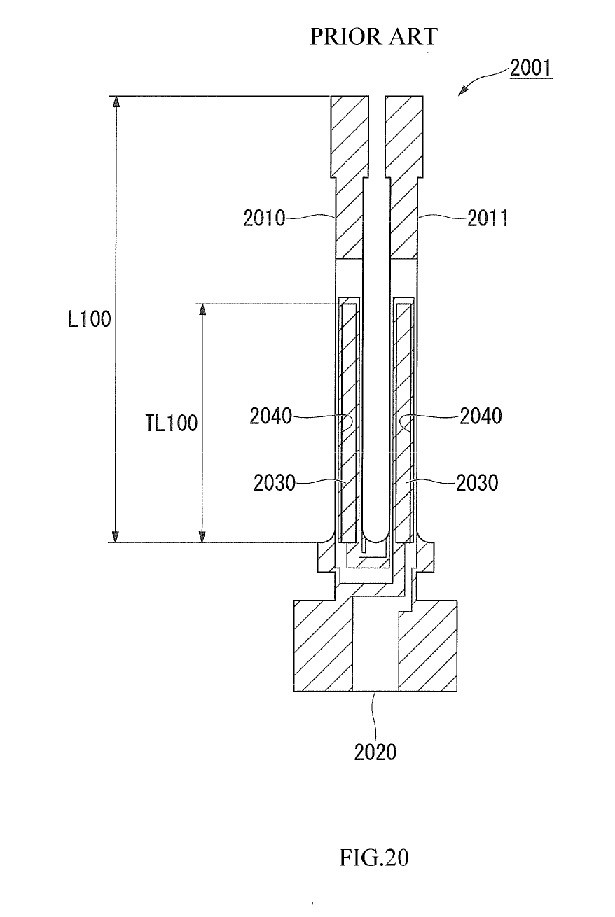

FIG. 21 is an explanatory diagram showing the behavior of the conventional piezoelectric vibrating strip.

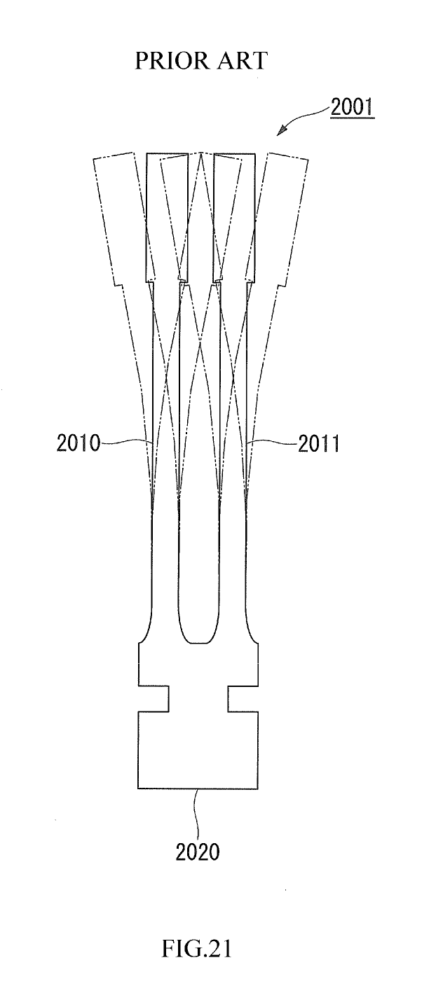

FIG. 22 is an explanatory diagram showing the behavior of the conventional piezoelectric vibrating strip when it vibrates in a second warp mode.

FIG. 23 is a graph showing changes in an R1 value and R2 value in the related art.

### DETAILED DESCRIPTION OF THE INVENTION

### First Embodiment

### (Piezoelectric Vibrator)

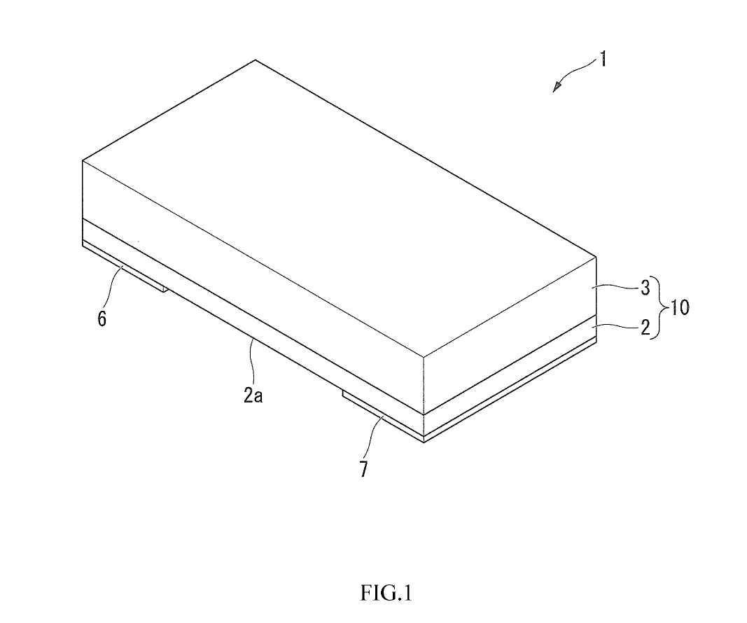

Next, a first embodiment of the present invention will be described with reference to FIG. 1 to FIG. 6.

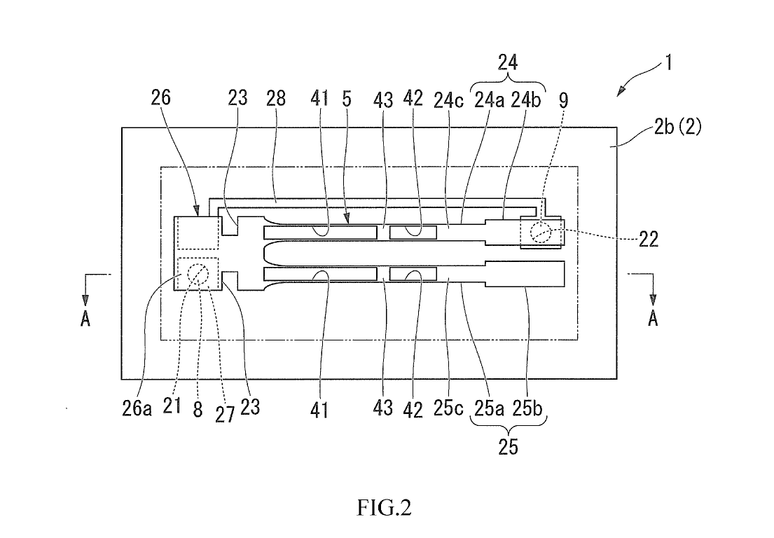

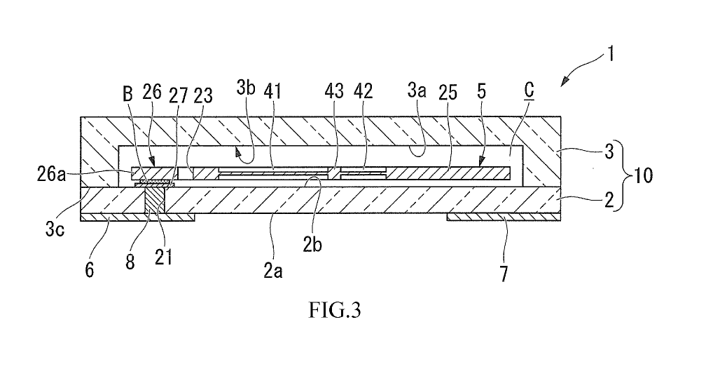

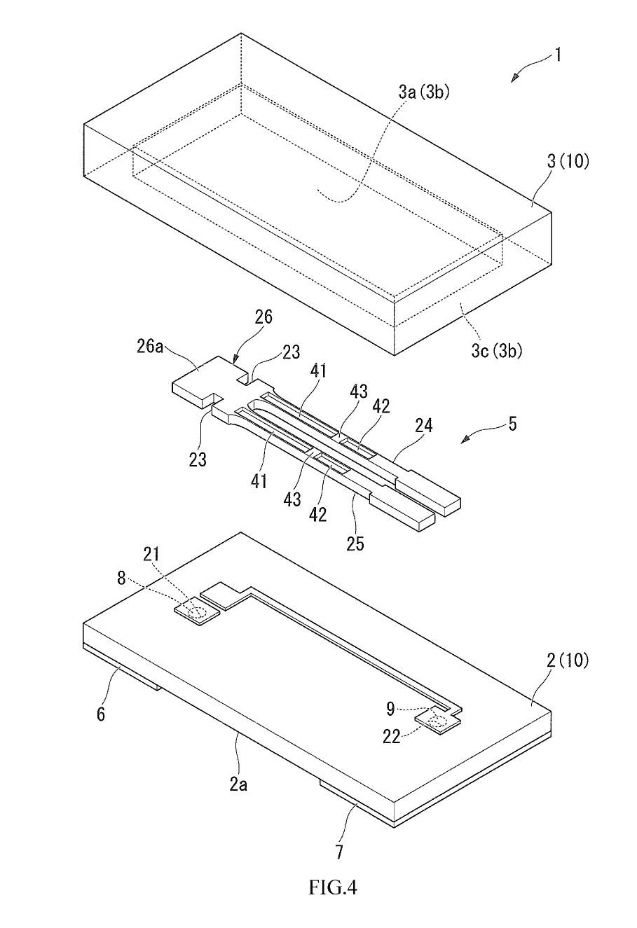

FIG. 1 is a perspective view showing the outer appearance of a piezoelectric vibrator in the present embodiment viewed from a lid substrate. FIG. 2 is a diagram of the internal structure of the piezoelectric vibrator and shows a piezoelectric vibrating strip viewed from above with the lid substrate removed therefrom. FIG. 3 is a section view taking along an A-A line in FIG. 2. FIG. 4 is an exploded perspective view of the piezoelectric vibrator.

As shown in FIG. 1 to FIG. 4, a piezoelectric vibrator 1 according to the present embodiment is of a surface-mounting type including a package 10 of box shape provided by anode-bonding a base substrate 2 to a lid substrate 3 with a bonding material, not shown, interposed between them, and a piezoelectric vibrating strip 5 housed in a cavity C of the package 10. The piezoelectric vibrating strip 5 is electrically connected to external electrodes 6 and 7 placed on a first face 2a (lower face in FIG. 3) of the base substrate 2 through a pair of through electrodes 8 and 9 passing through the base substrate 2.

The base substrate 2 is formed of a transparent insulating substrate made of a glass material, for example soda-lime glass in plate shape. The base substrate 2 has a pair of through holes 21 and 22 formed therein in which the pair of through electrodes 8 and 9 are formed.

The lid substrate 3 is a transparent insulating substrate made of a glass material, for example soda-lime glass similarly to the base substrate 2, and is formed in plate shape having a size which can be overlaid over the base substrate 2. The lid substrate 3 has a rectangular recess portion 3a formed therein in a first face 3b (lower face in FIG. 3). The lid substrate 3 is overlaid over the base substrate 2 with the recess portion 3a opposed to the base substrate 2 to form the cavity C for housing the piezoelectric vibrating strip 5.

With the cavity C formed in this manner, the lid substrate 3 is anode-bonded to the base substrate 2 through the bonding material. Specifically, the recess portion 3a is provided in the center on the first face 3b of the lid substrate 3, and a margin region 3c serving as a bonding face to the base substrate 2 is provided around the recess portion 3a. While the bonding material in the present embodiment is made of Si film, the bonding material may be formed of AL. Alternatively, the bonding material may be formed of Si bulk material having a resistance reduced by doping or the like. While the present embodiment is described in conjunction with the package using the glass material, the form of the package is not limited thereto. For example, a ceramic package using a ceramic substrate may be used. In this case, the ceramic substrate provides the base substrate on which a ceramic substrate of frame shape or a seal ring is overlaid to form the cavity. A metal lid or a glass lid may be used as the lid.

### (Piezoelectric Vibrating Strip)

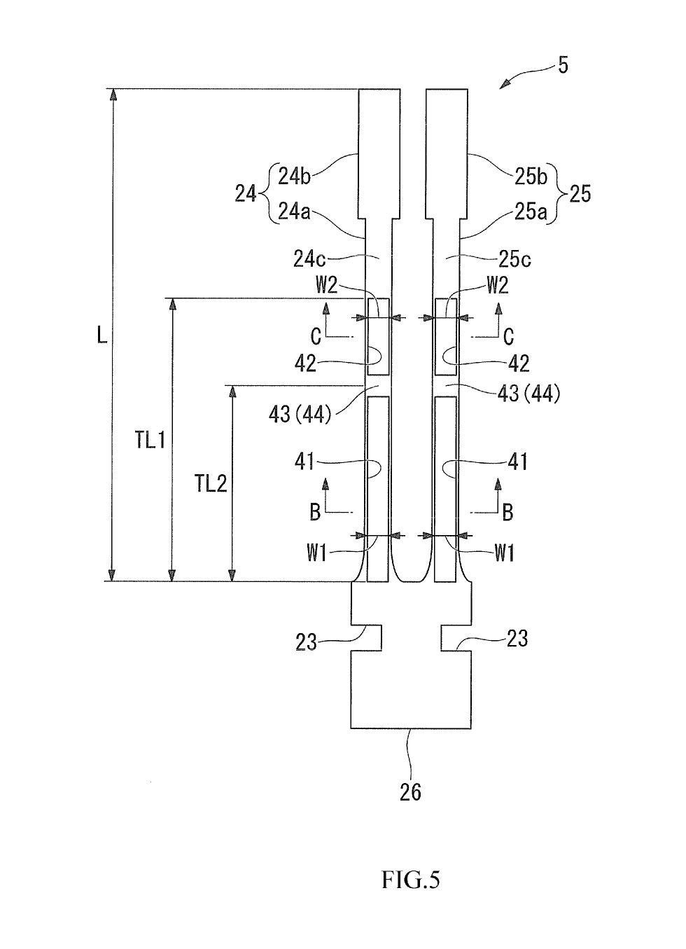

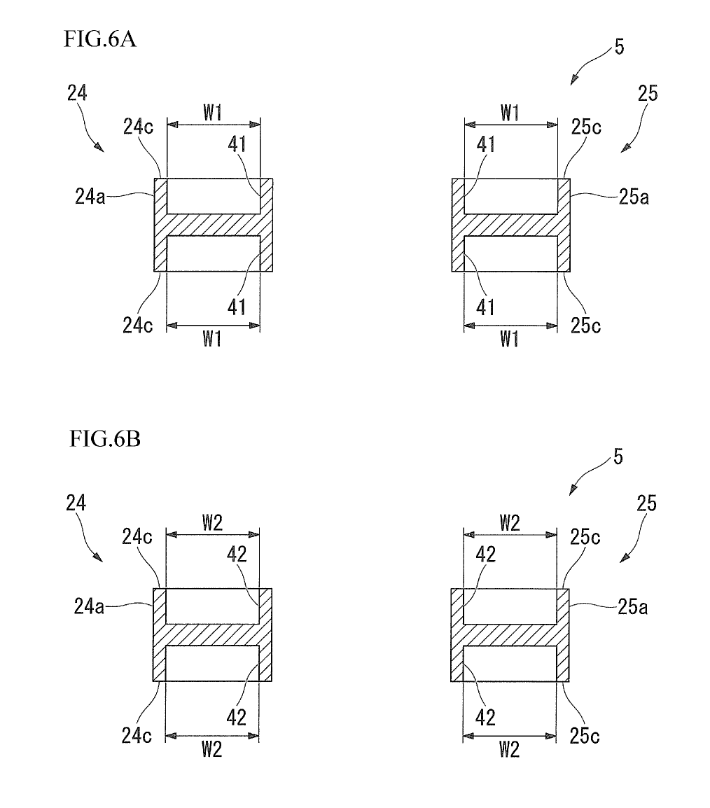

FIG. 5 is a plan view of the piezoelectric vibrating strip, FIG. 6A is a section view taken along a B-B line in FIG. 5, and FIG. 6B is a section view taken along a C-C line in FIG. 5.

As shown in FIG. 5 to FIG. 6B, the piezoelectric vibrating strip 5 is a vibrating strip of a tuning fork type made of piezoelectric material such as crystal, lithium tantalate, or lithium niobate, and vibrates when a predetermined voltage is applied thereto. The piezoelectric vibrating strip 5 is of the tuning fork type consisting of a pair of vibrating arm portions 24 and 25 extending in parallel and a base portion 26 integrally connecting and fixing the base end portions of the pair of vibrating arm portions 24 and 25 along the extending direction.

The base portion 26 has a recess portion 23 at each side in a width direction to reduce the width of the base portion 26. The recess portion 23 is provided for narrowing the route on which vibrations excited by the pair of vibrating arm portions 24 and 25 propagate to the base portion 26. This can confine the vibrations to the pair of vibrating arm portions 24 and 25 and prevent the vibrations from propagating to the base portion 26.

The pair of vibrating arm portions 24 and 25 is formed of arm portion bodies 24a and 25a extending from the base portion 26 and hammer portions 24b and 25b extending from the leading ends of the arm portion bodies 24a and 25a along the longitudinal direction of the arm portion bodies 24a and 25a and having larger widths than those of the arm portion bodies 24a and 25a by forming steps. The hammer portions 24b and 25b are set as free ends which vibrate in the width direction with the base portion 26 as the fixed end.

Exciting electrodes, not shown, are formed on the outer faces of the pair of vibrating arm portions 24 and 25 for vibrating the pair of vibrating arm portions 24 and 25. A mount electrode, not shown, is formed on the outer face of the base portion 26 and is connected to the exciting electrodes through a drawing electrode, not shown. When a predetermined voltage is applied to each of the electrodes, the interaction of the exciting electrodes on the pair of vibrating arm portions 24 and 25 vibrates the pair of vibrating arm portions 24 and 25 in a direction in which they are brought closer to or away from each other (in the width direction) at a predetermined resonance frequency.

Main faces 24c and 25c of the pair of vibrating arm portions 24 and 25 have groove portions formed therein to extend from the base ends toward the leading ends of the vibrating arm portions. These groove portions are broken in the longitudinal direction by a breaking portion 43. Of the broken groove, the groove portion placed closer to the base end is referred to as a first groove portion 41, and the groove portion placed closer to the leading end and at an interval from the first groove portion 41 is referred to as a second groove portion 42. The first groove portion 41 and the second groove portion 42 are formed along the longitudinal direction of the pair of vibrating arm portions 24 and 25.

In the pair of vibrating arm portions 24 and 25, the rigidity at the position where the breaking portion 43 is formed is higher than that at the positions where the groove portions 41 and 42 are formed.

Assuming that the overall length of each of the vibrating arm portions 24 and 25 is L, the distance TL1 between the base end of each of the vibrating arm portions 24 and 25 and the leading end of the second groove portion 42 is set to satisfy:

TL1≈0.6 L (1)

The distance TL2 between the base end of each of the vibrating arm portions 24 and 25 and the center of the breaking portion 43 is set to satisfy:

TL2≈L/2 (2)

A width W1 of the first groove portion 41 and a width W2 of the second groove portion 42 are set to satisfy:

W1≈W2 (3)

The groove depth H1 of the first groove portion 41 and the groove depth H2 of the second groove portion 42 are set to satisfy:

H1≈H2 (4)

Returning to FIG. 2 to FIG. 4, the piezoelectric vibrating strip 5 formed in this manner is bump-bonded onto routing electrodes 27 and 28 formed on a second face 2b (upper face in FIG. 3) of the base substrate 2 by using a bump B (see FIG. 3) made of gold or the like. Specifically, one of the exciting electrodes on the piezoelectric vibrating strip 5 is bump-bonded onto the one routing electrode 27 through one mount electrode formed on the face of the base portion 26 and the bump B, and the other exciting electrode is bump-bonded onto the other routing electrode 28 through the other mount electrode formed on the face of the base portion 26 and the bump B. When the ceramic package is used as the package, the piezoelectric vibrating strip 5 may be fixed and supported on the ceramic substrate, for example, by a conductive adhesive.

Thus, the piezoelectric vibrating strip 5 is supported with a spacing from the second face 2b of the base substrate 2 by bonding a portion of the base portion 26 (a portion away from each of the vibrating arm portions 24 and 25) onto the routing electrodes 27 and 28 on the package 10 and using the bonded portion (hereinafter referred to as a mount portion 26a) as a supporting and fixing point. The mount electrodes are electrically connected to the routing electrodes 27 and 28 at the mount portion 26a.

The external electrodes 6 and 7 are placed on both sides on the first face 2a of the base substrate 2 in the longitudinal direction and are electrically connected to the piezoelectric vibrating strip 5 through electrodes 8 and 9 and the routing electrodes 27 and 28, respectively. More specifically, the one external electrode 6 is electrically connected to one of the mount electrodes of the piezoelectric vibrating strip 5 through the one through electrode 8 and the one routing electrode 27. The other external electrode 7 is electrically connected to the other of the mount electrodes of the piezoelectric vibrating strip 5 through the other through electrode 9 and the other routing electrode 28.

The through electrodes 8 and 9 are conductive core materials fixed integrally to the through holes 21 and 22 and are formed to be flat at both ends in the through direction and to have substantially the same thickness as the thickness of the base substrate 2. The through electrodes 8 and 9 are responsible for completely closing the through holes 21 and 22 to maintain the hermeticity of the cavity C and for providing electrical continuity between external electrodes 6 and 7 and the routing electrodes 27 and 28. Specifically, the one through electrode 8 is located between the external electrode 6 and the base portion 26 of the piezoelectric vibrating strip 5 below the routing electrode 27, and the other through electrode 9 is located between the external electrode 7 and the vibrating arm portion 25 of the piezoelectric vibrating strip 5 below the routing electrode 28.

### (Method of Manufacturing Piezoelectric Vibrating Strip)

Then, a method of manufacturing the piezoelectric vibrating strip is described.

First, the outer shape pattern of the piezoelectric vibrating strip 5 having the pair of vibrating arm portions 24 and 25 and the base portion 26 is formed on both faces of a wafer, not shown, with a photolithography technique. At this point, a plurality of outer shape patterns are formed on the wafer.

Next, both faces of the wafer are etched by using the outer shape pattern as a mask. This can selectively remove the area not masked by the outer shape pattern to provide the outer shape of the piezoelectric vibrating strip 5. In this state, each of the piezoelectric vibrating strips 5 is connected to the wafer through a connecting portion, not shown.

The first groove portion 41 and the second groove portion 42 are formed in both main faces 24c and 25c of the vibrating arm portions 24 and 25 of the piezoelectric vibrating strip 5. Specifically, the area corresponding to the groove portions 41 and 42 are opened in the outer shape pattern described above with the lithography technique. Then, both faces of the wafer are etched (half etching) by using the outer shape pattern formed in this manner as the mask. This forms the first groove portion 41 and the second groove portion 42 in both main faces 24c and 25c of the vibrating arm portions 24 and 25.

Then, an electrode film is patterned on the outer face of the piezoelectric vibrating strip 5 with a known method to form the exciting electrodes, the routing electrodes, and the mount electrodes.

Finally, a cutting step is performed in which the connecting portion connecting the wafer to the piezoelectric vibrating strip 5 is cut to separate the plurality of piezoelectric vibrating strips 5 from the wafer for division. This allows the manufacture of the plurality of piezoelectric vibrating strips 5 of the tuning fork type at a time from the single wafer.

### (Operation of Piezoelectric Vibrator)

Next, the operation of the piezoelectric vibrator 1 is described.

For operating the piezoelectric vibrator 1, a predetermined driving voltage is applied to the external electrodes 6 and 7 formed on the base substrate 2. This can pass an electric current through each of the exciting electrodes on the piezoelectric vibrating strip 5 to vibrate the pair of vibrating arm portions 24 and 25 in the direction in which they are brought closer to or away from each other (width direction) at a predetermined frequency. The vibrations of the pair of vibrating arm portions 24 and 25 can be used to achieve the application as the time source, the timing source for a control signal, the reference signal source or the like.

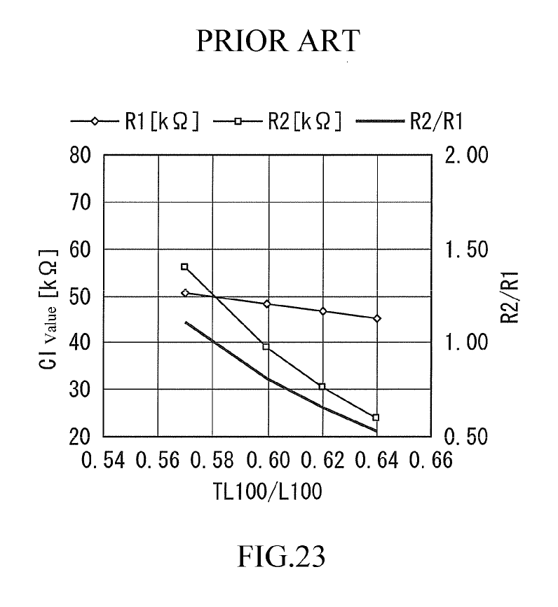

The first groove portion 41 and the second groove portion 42 are formed on both main faces 24c and 25c of the vibrating arm portions 24 and 25 with the breaking portion 43 interposed between them. In addition, the distance TL1 between the base ends of the vibrating arm portions 24 and 25 and the leading end of the second groove portion 42 is set to approximately 0.6 L assuming that the overall length of each of the vibrating arm portions 24 and 25 is L (see FIG. 5). As described above with reference to FIG. 23, when the length of the groove portion relative to the overall length of the vibrating arm portion exceeds approximately 0.58, R1 becomes larger than R2 to cause the piezoelectric vibrating strip to vibrate easily in the second warp mode. In the present embodiment, the presence of the breaking portion 43 allows R1 to be smaller than R2 even when the length of the groove portion is approximately 0.6 L.

R1 smaller than R2 is provided for the following reasons even when the length of the groove portion is approximately 0.6 L. Specifically, the rigidity at the position of the pair of vibrating arm portions 24 and 25 where the breaking portion 43 is formed is higher than that at the positions where the groove portions 41 and 42 are formed. In addition, the position where the breaking portion 43 is formed corresponds to the portion between the nodes of vibrations in the second warp vibration. Thus, the breaking portion 43 serves as a “portion which prevents the vibrations in the second warp mode,” that is, a “deformation suppressing portion” which prevents second warp deformation of the pair of vibrating arm portions 24 and 25.

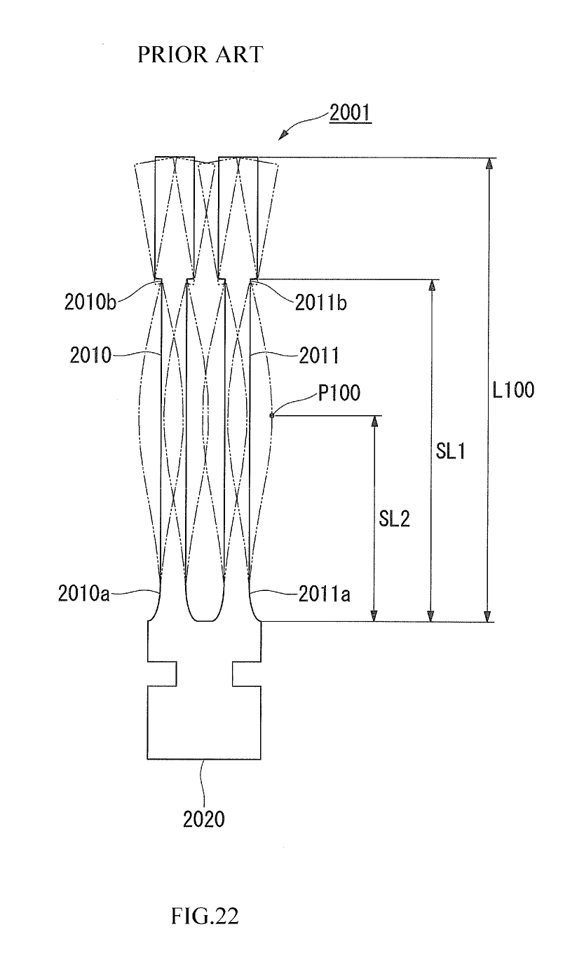

In addition, the distance TL2 between the base end of the vibrating arm portions 24 and 25 and the center of the breaking portion 43 is set to satisfy the expression (2) (see FIG. 5). Specifically, the breaking portion 43 is formed at the position where the maximum displacement is produced when the pair of vibration arm portions 24 and 25 vibrates in the second warp mode (see the maximum amplitude portion P100 in FIG. 22 in the related art). In other words, the distance TL2 between the base end of the vibrating arm portions 24 and 25 and the center of the breaking portion 43 is set to be substantially the same as the distance SL2 between the base end of the vibrating arm portions 2010 and 2011 and the maximum amplitude portion P100 in FIG. 22 in the related art. This prevents the pair of vibrating arm portions 24 and 25 from vibrating in the second warp mode due to unnecessary warp deformation, and even when the length TL1 of the groove portion is increased to reduce R1, R1 smaller than R2 can be maintained, and the pair of vibrating arm portions 24 and 24 can be vibrated in the fundamental mode.

### (Effects)

According to the first embodiment, the first groove portion 41 and the second groove portion 42 are formed in both main faces 24c and 25c of the pair of vibrating arm portions 24 and 25 and the breaking portion 43 placed between the groove portions 41 and 42 is formed to allow the vibrating arm portions 24 and 25 to vibrate in the fundamental mode even when the distance TL1 (length of the groove portion) between the base end of the vibrating arm portions 24 and 25 and the leading end of the second groove portion 42 is set to satisfy the expression (1), that is, even when the overall length of the first groove portion 41 and the second groove portion 42 including the breaking portion 43 is set to be a half or more of the overall length of the vibrating arm portions 24 and 25. This can prevent the pair of vibrating arm portions 24 and 25 from vibrating in the second warp mode while increasing the length of the groove portion to reduce R1.

The breaking portion 43 is allowed to serve as the deformation suppressing portion which prevents the warp deformation of the pair of vibrating arm portions 24 and 25. This can prevent an increase in the manufacture cost of the piezoelectric vibrating strip 5 as compared with the case where special work is performed between the first groove portion 41 and the second groove portion 42 in order to prevent the deformation of the pair of vibrating arm portions 24 and 25. While the position of the deformation suppressing portion is set in the present embodiment such that TL2 is approximately L/2, the effect of increasing R2 can be provided as long as the position is present between the nodes in the second warp mode. More effectively, the deformation suppressing portion may be provided substantially at the center between the nodes, that is, at the position where the displacement is at the maximum. In the present embodiment, the position is set to satisfy TL2=approximately L/2.

The distance TL2 between the center of the breaking portion 43 formed in the vibrating arm portions 24 and 25 and the base end of the vibrating arm portions 24 and 25 is set to be substantially the same as the distance between the position where the maximum displacement is produced when the pair of vibrating arm portions 24 and 25 vibrates in the second warp mode and the base end of the vibrating arm portions 24 and 25. This can effectively prevent the pair of vibrating arm portions 24 and 25 from vibrating in the second warp mode. While the present embodiment has been described in conjunction with the configuration in which the hammer portions 24b and 25b are provided and the recess portion 23 is provided in the base portion 26, the shape of the piezoelectric vibrating strip to which the present invention is applicable is not limited thereto, and the hammer portion or the recess portion may not be provided. The groove portion may be provided on one of the main face or the back face in the vibrating arm portions 24 and 25 (this applies also to the other embodiments described below).

### Second Embodiment

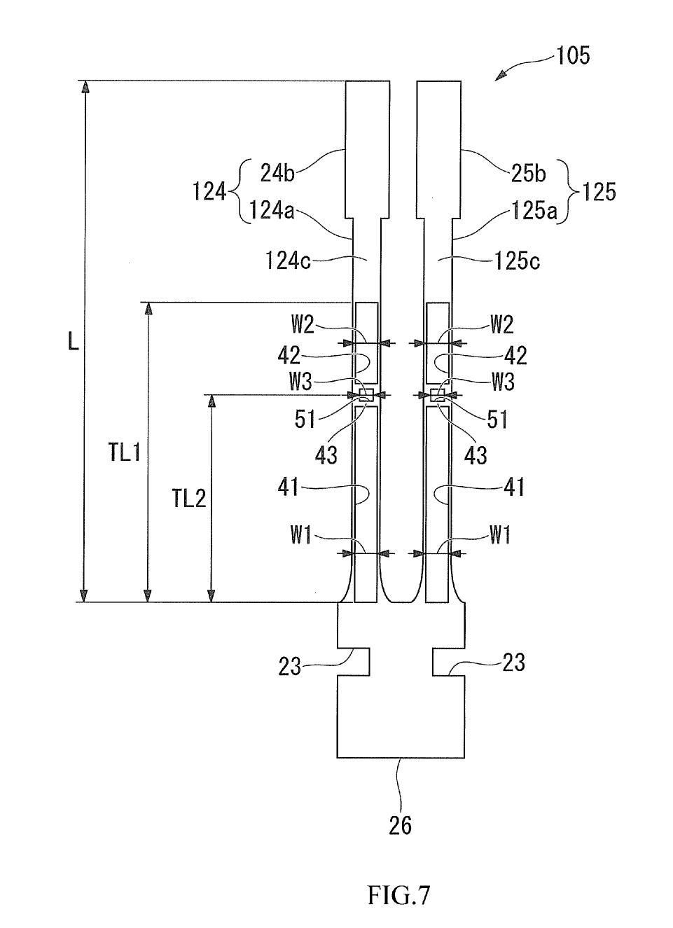

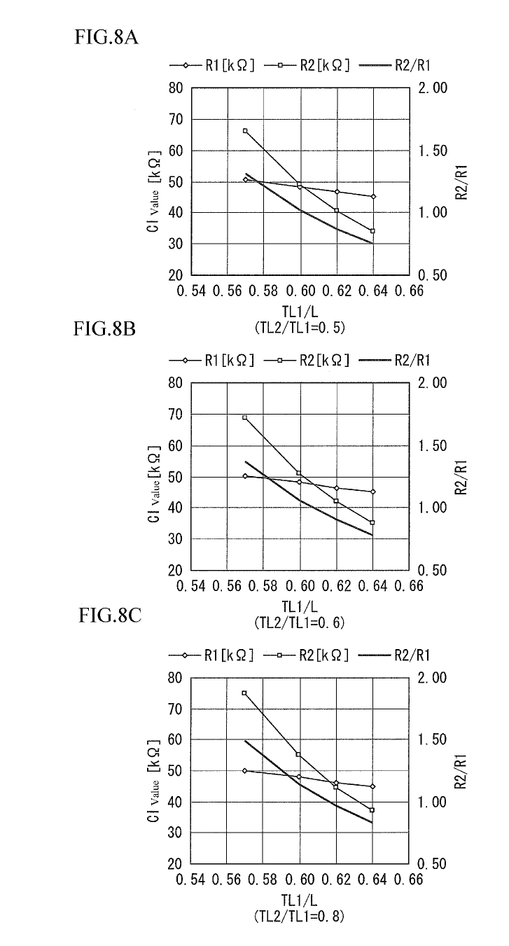

Next, a second embodiment of the present invention will be described by using FIG. 1 and FIG. 3 again and with reference to FIG. 7 and FIG. 8. The same aspects as those in the first embodiment are described with the same reference numerals (this applies also to the other embodiments described below).

FIG. 7 is a plan view of a piezoelectric vibrating strip in the second embodiment.

The second embodiment is similar to the first embodiment described above in the basic configuration (this applies also to the other embodiments describe below) in which a piezoelectric vibrator 1 is of a surface mounting type including a package 10 of box shape provided by anode-bonding a base substrate 2 to a lid substrate 3 with a bonding material, not shown, interposed between them, and a piezoelectric vibrating strip 105 housed in a cavity C of the package 10 (or may be a ceramic package), the piezoelectric vibrating strip 105 are electrically connected to external electrodes 6 and 7 placed on a first face 2a (lower face in FIG. 3) of the base substrate 2 through a pair of through electrodes 8 and 9 passing through the base substrate 2, the piezoelectric vibrating strip 105 is a vibrating strip of a tuning fork type formed of a piezoelectric material such as crystal, lithium tantalate, and lithium niobate and consists of a pair of vibrating arm portions 124 and 125 extending in parallel and a base portion 26 integrally connecting and fixing the base end portions of the pair of vibrating arm portions 124 and 125 along the extending direction, the pair of vibrating arm portions 124 and 125 is formed of arm portion bodies 124a and 125a extending from the base portion 26 and hammer portions 24b and 25b extending from the leading ends of the arm portion bodies 124a and 125a along the longitudinal direction of the arm portion bodies 124a and 125a and having larger widths than those of the arm portion bodies 124a and 125a by forming steps, and the hammer portions 24b and 25b are set as free ends which vibrate in the width direction with the base portion 26 as the fixed end.

The second embodiment differs from the first embodiment in that the breaking portion 43 is formed between the first groove portion 41 and the second groove portion 42 in the pair of vibrating arm portions 24 and 25 in the first embodiment, whereas a narrow groove portion 51 (recess portion) is formed in a breaking portion 43 between a first groove portion 41 and a second groove portion 42 in the pair of vibrating arm portions 124 and 125 in the second embodiment.

More specifically, as shown in FIG. 7, the narrow groove portion 51 is formed between the first groove portion 41 and the second groove portion 42 in main faces 124c and 125c of the vibrating arm portions 124 and 125. The narrow groove portion 51 has a width W3 which is set to be smaller than the width W1 of the first groove portion 41 and the width W2 of the second groove portion 42. The narrow groove portion 51 is formed with a spacing from the first groove portion 41 and the second groove portion 42 to avoid communication with them.

With this formation, the vibrating arm portions 124 and 125 have improved rigidity at the narrow groove portion 51 (as compared with the case where the groove is formed with the same groove length and the constant width), so that the second embodiment can achieve the advantages similar to those in the first embodiment described above.

The advantages of the second embodiment will be described more specifically with reference to FIG. 8.

FIGS. 8A to 8C show graphs illustrating changes in an R1 value and an R2 value in the second embodiment, in which the vertical axis represents the R1 value and the R2 value and the horizontal axis represents TL1/L. FIG. 8A shows the case where the distance TL2 between the base end of the vibrating arm portions 124 and 125 and the center of the breaking portion 43 divided by the distance TL1 between the base end of the vibrating arm portions 124 and 125 and the leading end of the second groove portion 42 (hereinafter referred to simply as “TL2/TL1”) is 0.5. FIG. 8B shows the case where the value of TL2/TL1 is 0.6. FIG. 8C shows the case where the value of TL2/TL1 is 0.8.

As shown in FIG. 8A in which TL2/TL1 is 0.5, it can be seen that the R2 value becomes smaller than the R1 value when the value of TL1/L reaches approximately 0.6.

As shown in FIG. 8B in which TL2/TL1 is 0.6, it can be seen that the R2 value becomes smaller than the R1 value when the value of TL1/L reaches approximately 0.61.

As shown in FIG. 8C in which TL2/TL1 is 0.8, it can be seen that the R2 value becomes smaller than the R1 value when the value of TL1/L reaches approximately 0.62.

Thus, according to the second embodiment described above, the pair of vibrating arm portions 124 and 125 can be prevented from vibrating in the second warp mode while reducing the CI value as compared with the related art (see FIG. 23).

As apparent from FIG. 8A to FIG. 8C, the distance TL2 between the base end of the vibrating arm portions 124 and 125 and the center of the breaking portion 43 and the distance TL1 between the base end of the vibrating arm portions 124 and 125 and the leading end of the second groove portion 42 can be set to satisfy:

TL2/TL1≧0.5 (5)

to effectively prevent the vibration of the pair of vibrating arm portions 124 and 125 in the second warp mode. More effectively, the setting as TL2/TL1≈0.8 allows the relationship of R1<R2 to be maintained even when the length TL1 of the groove portion is increased.

### Third Embodiment

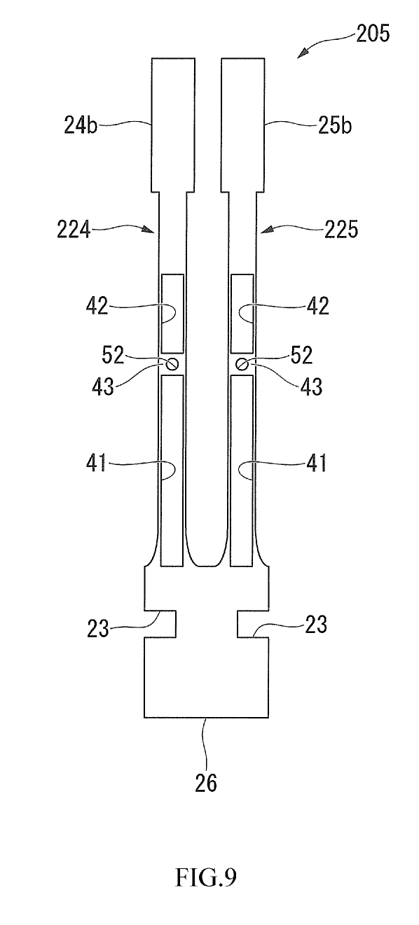

Next, a third embodiment of the present invention will be described with reference to FIG. 9.

FIG. 9 is a plan view of a piezoelectric vibrating strip in the third embodiment.

As shown in FIG. 9, a piezoelectric vibrating strip 205 in the third embodiment differs from the piezoelectric vibrating strip 105 in the second embodiment in that a groove formed in a breaking portion 43 of a pair of vibrating arm portions 224 and 225 in the third embodiment has a shape different from that of the groove formed in the breaking portion 43 of the pair of vibrating arm portions 124 and 125 in the second embodiment.

More specifically, as shown in FIG. 9, a groove portion 52 having a generally circular shape in plan view in a thickness direction is formed in the breaking portion 43 of the vibrating arm portions 224 and 225. With this formation, the vibrating arm portions 224 and 225 have improved rigidity at the groove portion 52 (as compared with the case where the groove is formed with the same groove length and the constant width), so that the third embodiment can achieve the advantages similar to those in the first embodiment described above.

### Fourth Embodiment

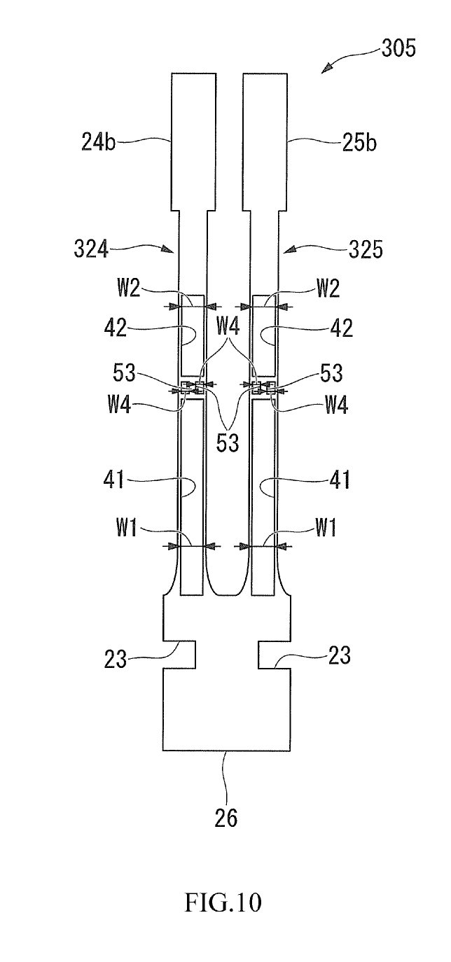

Next, a fourth embodiment of the present invention will be described with reference to FIG. 10.

FIG. 10 is a plan view of a piezoelectric vibrating strip in the fourth embodiment.

As shown in FIG. 10, a piezoelectric vibrating strip 305 in the fourth embodiment differs from the piezoelectric vibrating strip 105 in the second embodiment in that a groove formed in a breaking portion 43 of a pair of vibrating arm portions 324 and 325 in the fourth embodiment has a shape different from that of the groove formed in the breaking portion 43 of the pair of vibrating arm portions 124 and 125 in the second embodiment.

More specifically, as shown in FIG. 10, two narrow grooves 53 are placed side by side in the breaking portion 43 of the pair of vibrating arm portions 324 and 325. Each of the narrow groove portions 53 has a width W4 which is set to be smaller than a half of the width W1 of a first groove portion 41 and a half of the width W2 of a second groove portion. Thus, each of the narrow groove portions 53 is placed with a spacing from the first groove portion 41 and the second groove portion 42.

Even when the two narrow groove portions 53 are formed in the breaking portion 43 in this manner, the vibrating arm portions 324 and 325 have improved rigidity at the narrow groove portions 53 (as compared with the case where the groove is formed with the same groove length and the constant width), so that the fourth embodiment can achieve the advantages similar to those in the first embodiment described above.

While the fourth embodiment has been described in conjunction with the case where the two narrow groove portions 53 are formed in the breaking portion 43, the present invention is not limited thereto, and three or more narrow groove portions may be formed in the breaking portion 43.

### Fifth Embodiment

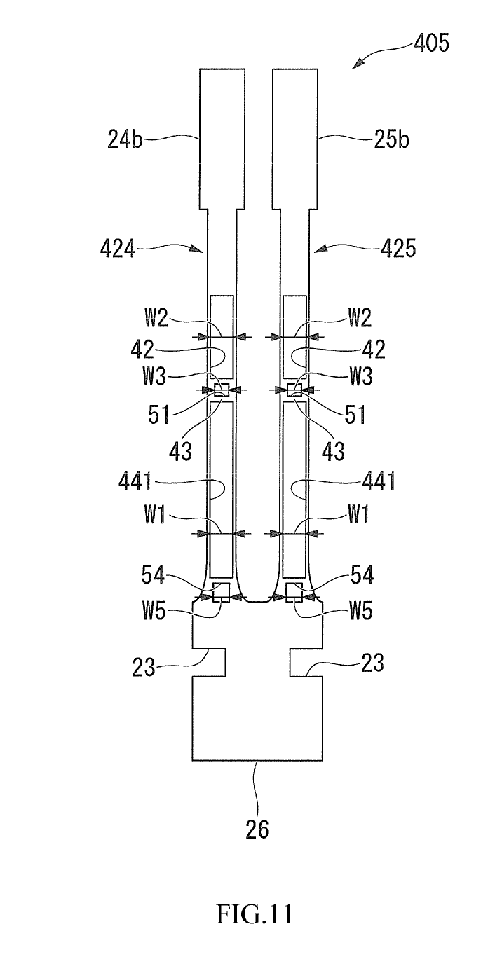

Next, a fifth embodiment of the present invention will be described with reference to FIG. 11.

FIG. 11 is a plan view of a piezoelectric vibrating strip in the fifth embodiment.

As shown in FIG. 11, a piezoelectric vibrating strip 405 in the fifth embodiment differs from the piezoelectric vibrating strip 105 in the second embodiment in that a narrow groove portion 54 is formed in base ends of a pair of vibrating arm portions 324 and 325 in the fifth embodiment, whereas no narrow groove portions 54 are formed in the piezoelectric vibrating strip 105 in the second embodiment.

More specifically, as shown in FIG. 11, the narrow groove portion 54 is formed at the base ends in both main faces 424c and 425c of the pair of vibrating arm portions 424 and 425. The narrow groove portion 54 has a width W5 which is set to be smaller than the width W1 of a first groove portion 41 and the width W2 of a second groove portion 42. The first groove portion 441 is formed with a spacing from the narrow groove portion 54 to avoid communication with the narrow groove portion 54.

With this formation, the vibrating arm portions 424 and 425 have improved rigidity at the narrow groove portions 51 (as compared with the case where the groove is formed with the same groove length and the constant width), so that the fifth embodiment can achieve the advantages similar to those in the first embodiment described above. In addition, the formation of the narrow groove portion 54 on the base end can improve the strength of the vibrating arm portions 424 and 425 on the base end.

### Sixth Embodiment

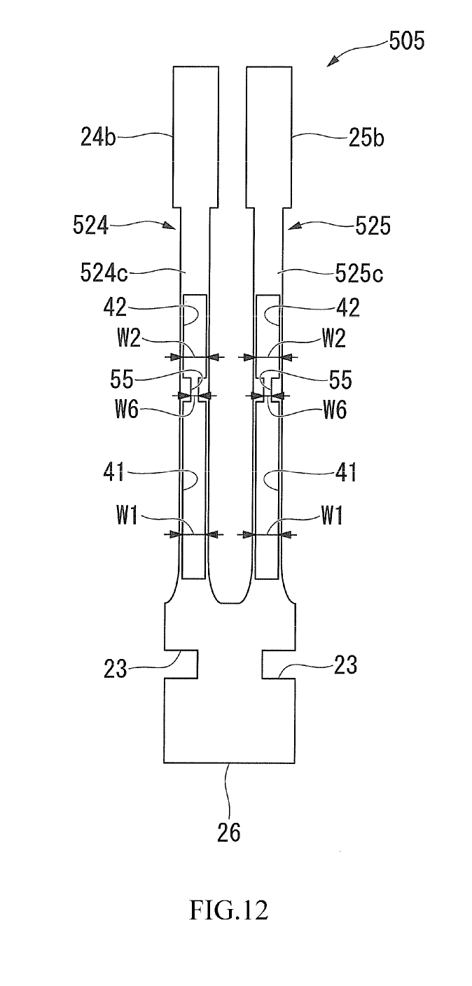

Next, a sixth embodiment of the present invention will be described with reference to FIG. 12.

FIG. 12 is a plan view of a piezoelectric vibrating strip in the sixth embodiment.

As shown in FIG. 12, the sixth embodiment differs from the first embodiment in that the breaking portion 43 is formed between the first groove portion 41 and the second groove portion 42 in the pair of vibrating arm portions 24 and 25 in the first embodiment, whereas a narrow groove portion 55 (reduced width portion) couples a first groove portion 41 to a second groove portion 42 in a pair of vibrating arm portions 524 and 525 in the sixth embodiment.

More specifically, as shown in FIG. 12, the narrow groove portion 55 is formed between the first groove portion 41 and the second groove portion 42 in both main faces 524c and 525c of the pair of vibrating arm portions 524 and 525. The narrow groove portion 55 has a width W6 which is set to be smaller than the width W1 of the first groove portion 41 and the width W2 of the second groove portion 42, that is, it can be said to be the reduced width portion. In addition, the narrow groove portion 55 is formed to extend to the first groove portion 41 and the second groove portion 42 and to communicate with the portions 41 and 42. With this formation, the vibrating arm portions 524 and 525 have improved rigidity at the narrow groove portions 55 (as compared with the case where the groove is formed with the same groove length and the constant width), so that the sixth embodiment can achieve the advantages similar to those in the first embodiment described above.

### Seventh Embodiment

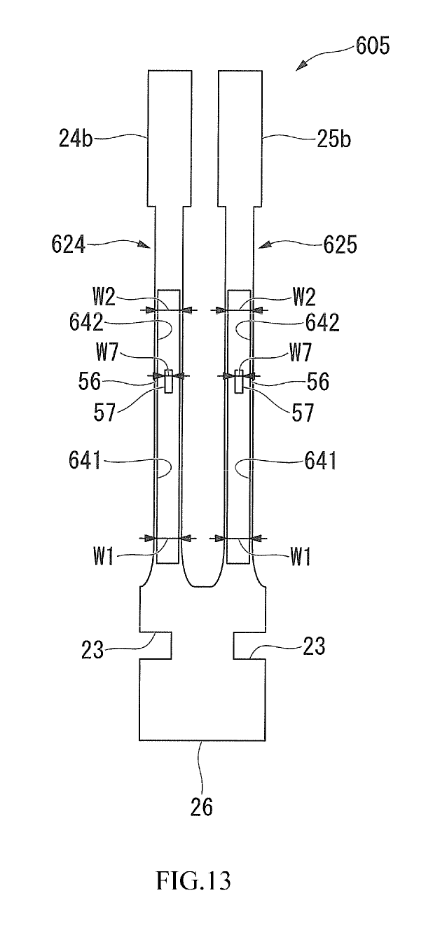

Next, a seventh embodiment of the present invention will be described with reference to FIG. 13.

FIG. 13 is a plan view of a piezoelectric vibrating strip in the seventh embodiment.

As shown in FIG. 13, the seventh embodiment differs from the first embodiment in that the breaking portion 43 is formed between the first groove portion 41 and the second groove portion 42 in the pair of vibrating arm portions 24 and 25 in the first embodiment, whereas a first groove portion 641 and a second groove portion 642 formed in a pair of vibrating arm portions 624 and 625 in the seventh embodiment are connected to each other and a rib 57 is formed in a connecting portion 56 which connects the first groove portion 641 to the second groove portion 642. The rib 57 serves as a “deformation suppressing portion” for the second warp vibration.

The rib 57 has a width W7 which is set to be smaller than the width W1 of the first groove portion 41 and the width W2 of the second groove portion 42. With the formation of the rib 57, the deformation area have increased rigidity in the second warp mode even when the width W1 of the first groove portion 641 and the second groove portion 642 are continuously formed. Thus, the rib 57 serves as the deformation suppressing portion which suppresses warp deformation of the pair of vibrating arm portions 624 and 625.

According to the seventh embodiment described above, the vibrating arm portions 624 and 625 have improved rigidity at the rib 57 (as compared with the case where no rib is formed), so that the seventh embodiment can achieve the advantages similar to those in the first embodiment described above.

### Eighth Embodiment

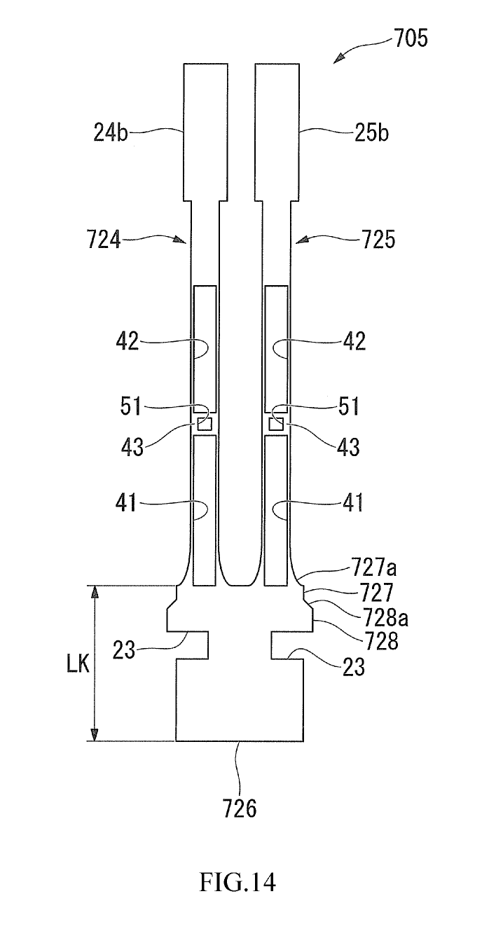

Next, an eighth embodiment of the present invention will be described with reference to FIG. 14.

FIG. 14 is a plan view of a piezoelectric vibrating strip in the eighth embodiment.

As shown in FIG. 14, the eighth embodiment differs from the second embodiment in that the shape of the base portion 26 forming part of the piezoelectric vibrating strip 105 in the second embodiment is different from the shape of a base portion 72 forming part of a piezoelectric vibrating strip 705 in the eighth embodiment.

More specifically, as shown in FIG. 14, the base portion 726 in the eighth embodiment is widened in steps from the side connecting to a pair of vibrating arm portions 724 and 725 toward the opposite side to the vibrating arm portions 724 and 725 (lower side in FIG. 14). Specifically, the base portion 726 has a first base portion 727 closer to the side connecting to the pair of vibrating arm portions 724 and 725 and a second base portion 728 coupled to the first base portion 727 on the side opposite to the pair of vibrating arm portions 724 and 725 and increased in width as compared with the first base portion 727 (so-called two-stage base portion type).

Inclined faces 727a and 728a are formed on a portion of the first base portion 727 connecting to the vibrating arm portions 724 and 725 and a portion between the base portions 727 and 728 such that the width is increased gradually from the vibrating arm portions 724 and 725 toward the side opposite to the vibrating arm portions 724 and 725.

Thus, according to the eighth embodiment described above, the first base portion 727 formed to have the smaller width can narrow the route on which vibrations excited by the pair of vibrating arm portions 724 and 725 propagate to the second base portion 728. This can confine the vibrations to the pair of vibrating arm portions 724 and 725 and prevent the vibrations from leaking to the second base portion 728. This can effectively suppress the vibration leaks, suppress the increase in CI value, and prevent reduced quality of output signals.

In addition, since the volume of the base portion 726 can be increased without increasing a length LK of the base portion 726, and the second base portion 728 formed to have the larger width can be used for mounting, the mountability can be enhanced.

The first to seventh embodiments have been described in conjunction with the case the recess portion 23 is formed to reduce the width of the base portion 26 on both sides in the width direction of the base portion 26 forming part of the piezoelectric vibrating strips 5, 105, 205, 305, 405, 505, and 605. The eighth embodiment has been described in conjunction with the case where the recess portion 23 is formed on both sides in the width direction of the base portion 726 forming part of the piezoelectric vibrating strip 705. However, the present invention is not limited thereto, and the recess portion 23 may not be formed in the base portions 26 and 726.

### Ninth Embodiment

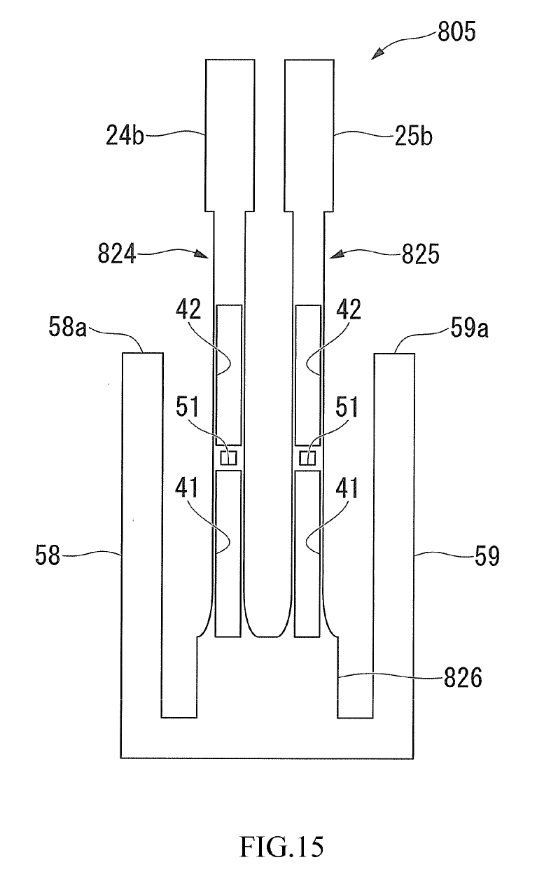

Next, a ninth embodiment of the present invention will be described with reference to FIG. 15.

FIG. 15 is a plan view of a piezoelectric vibrating strip in the ninth embodiment.

As shown in FIG. 15, the ninth embodiment differs from the second embodiment in that a piezoelectric vibrating strip 805 in the ninth embodiment has side arms 58 and 59 integrally formed on both sides in the width direction of a base portion 826 (so-called side arm type), whereas the base portion 26 of the piezoelectric vibrating strip 105 in the second embodiment has no side arms 58 integrally formed.

More specifically, the side arms 58 and 59 are formed to extend from the end of the base portion 826 opposite to a pair of vibrating arm portions 824 and 825 (lower end in FIG. 15) toward both sides in the width direction and then bend and extend along the longitudinal direction of the vibrating arm portions 824 and 825 and toward the leading ends of the vibrating arm portions 824 and 825. Leading end portions 58a and 59a of the side arms 58 and 59 extend to a portion closer to the leading ends of the vibrating arm portions 824 and 825 than a generally central portion of a second groove portion 42 in the longitudinal direction thereof.

With the configuration described above, the bonding portions 58a and 59a of the side arms 58 and 59 can function as a mount portion which can be used for mounting on a package, for example.

Thus, according to the ninth embodiment described above, in addition to the advantages similar to those in the second embodiment, the increased distance can be ensured in the base portion 826 between the connecting portion to the vibrating arm portions 824 and 825 and the mount portion (leading end portions 58a and 59a of the side arms 58 and 59). This can suppress vibration leaks, an increase in CI value, and reduced quality of output signals without increasing the overall length of the piezoelectric vibrating strip 805.

### Tenth Embodiment

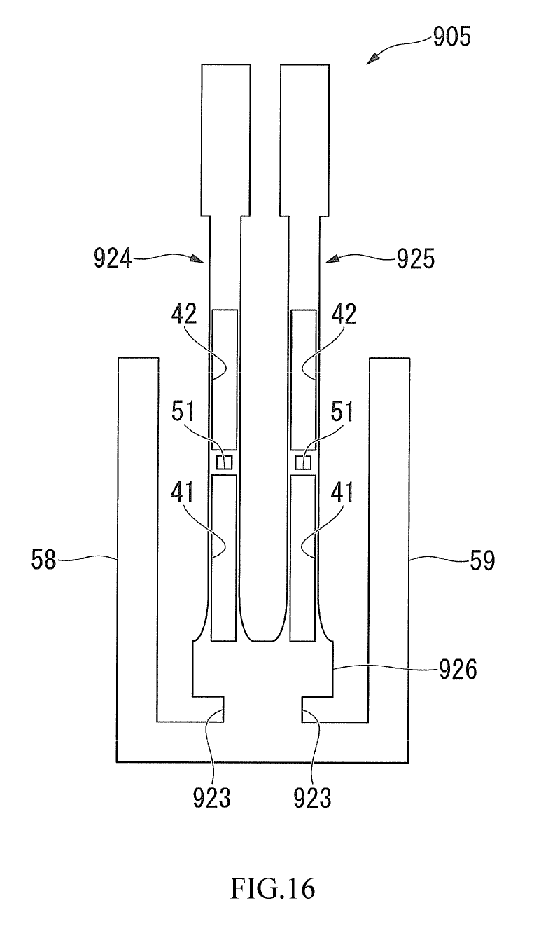

Next, a tenth embodiment of the present invention will be described with reference to FIG. 16.

FIG. 16 is a plan view of a piezoelectric vibrating strip in the tenth embodiment.

As shown in FIG. 16, the tenth embodiment differs from the ninth embodiment in that a recess portion 923 is formed on both sides in a width direction of a base portion 926 in the tenth embodiment, whereas no recess portion 923 is formed on both sides in the width direction of the base portion 826 in the ninth embodiment.

This configuration can narrow the route on which vibrations excited by a pair of vibrating arm portions 924 and 925 propagate the base portion 926.

Thus, according to the tenth embodiment described above, in addition to the advantages similar to those in the ninth embodiment, the vibrations can be confined to the pair of vibrating arm portions 924 and 925 and can be prevented from leaking to the base portion 926, so that the increase in CI value can be further prevented.

### (Oscillator)

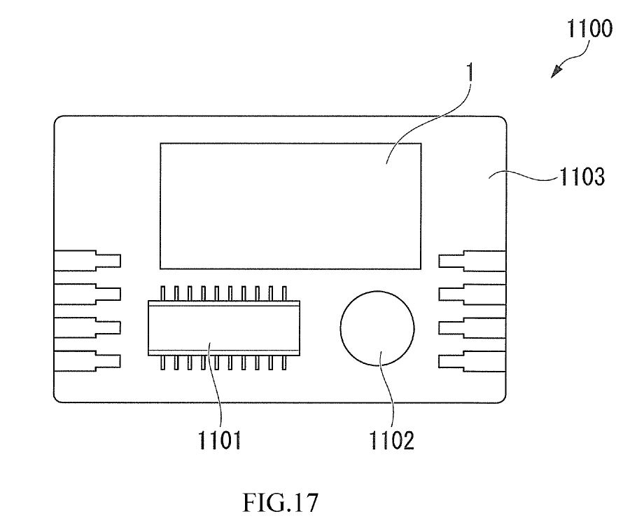

Next, an embodiment of an oscillator according to the present invention will be described with reference to FIG. 17.

FIG. 17 is a schematic diagram showing the embodiment of the oscillator.

As shown in FIG. 17, an oscillator 1100 in the present embodiment includes the piezoelectric vibrator 1 as an oscillator electrically connected to an integrated circuit 1101. The oscillator 1100 includes a substrate 1103 on which an electronic part 1102 such as a capacitor is mounted. The abovementioned integrated circuit 1101 for the oscillator is mounted on the substrate 1103, and the piezoelectric oscillator 1 is mounted near the integrated circuit 1101. The electronic part 1102, the integrated circuit 1101, and the piezoelectric vibrator 1 are connected electrically to each other through a wiring pattern, not shown. Each of the components is molded with a resin, not shown.

In the oscillator 1101 formed in this manner, when a voltage is applied to the piezoelectric vibrator 1, the piezoelectric vibrating strip 5 (105, 205, 305, 405, 505, 605, 705, 805, 905) within the piezoelectric vibrator 1 vibrates. The vibrations are converted into an electric signal through the piezoelectric property provided by the piezoelectric vibrating strip 5 and are input as the electric signal to the integrated circuit 1101. The input electric signal is subjected to various types of processing in the integrated circuit 1101 and is output as a frequency signal. The piezoelectric vibrator 1 serves as the oscillator in this manner.

When the configuration of the integrated circuit 1101 is selectively set as needed for a RTC (Real Time Clock) module or the like, additional functions can be provided such as control of the operation day or time of the device and an external device, provision of time or calendar and the like in addition to the single-function oscillator for clock.

As described above, according to the oscillator 1100 of the present embodiment, the piezoelectric vibrator 1 is included which has a high strength and can suppress the CI value at a low level with a smaller size and higher performance, so that the oscillator 1100 can be provided with high reliability and high performance.

### (Electronic Device)

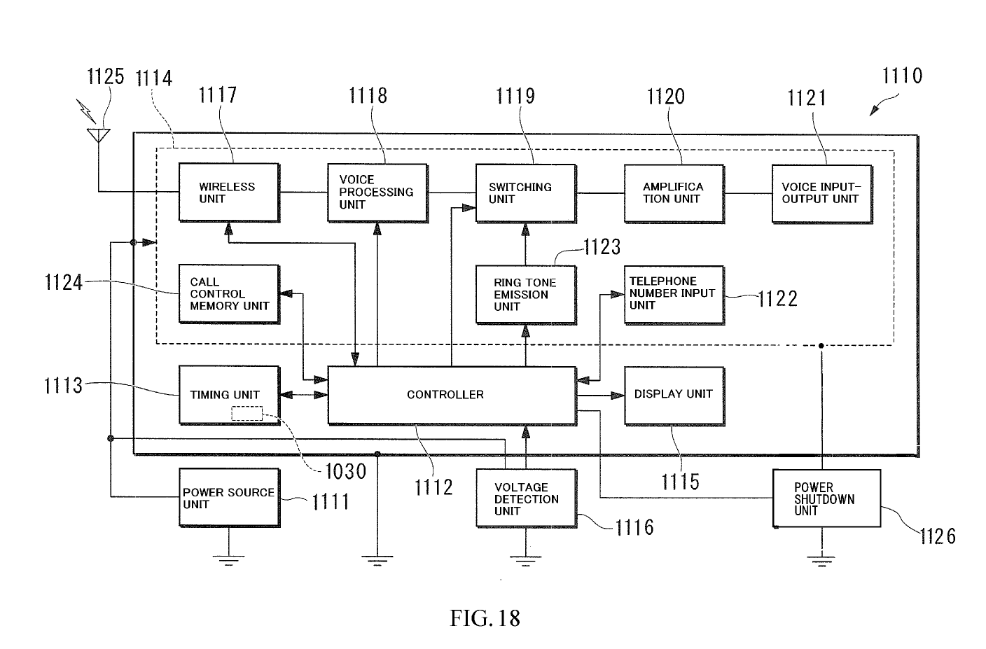

Next, an embodiment of an electronic device according to the present invention will be described with reference to FIG. 18. The electronic device is described by using a portable information device (electronic device) 1110 having the piezoelectric vibrator 1 described above as an example.

The portable information device 1110 in the present embodiment is represented by a cellular phone, for example, and is provided by enhancing and improving a wristwatch in the related art. The outer appearance is similar to that of the wristwatch with a liquid crystal display placed on a portion corresponding to a dial, and the current time or the like can be displayed on the screen. For use as a communication device, the device can be removed from the wrist and communication can be performed similarly to the cellular phone in the related art by using a speaker and a microphone contained in a band. However, the device is significantly reduced in size and weight as compared with the conventional cellular phone.

Next, the configuration of the portable information device 1110 in the present embodiment will be described.

FIG. 18 shows a schematic diagram of the portable information device.

As shown in FIG. 18, the portable information device 1110 includes the piezoelectric vibrator 1 and a power source section 1111 for supplying the power. The power source section 1111 is formed of a lithium-ion secondary battery, by way of example. The power source section 1111 is connected in parallel to a control section 1112 for performing various types of control, a time measuring section 1113 for counting time or the like, a communicating section 1114 for performing communication with the outside, a display section 1115 for displaying various types of information, and a voltage detecting section 1116 for detecting the voltage of each of functioning sections. The power source section 1111 supplies the power to each of the functioning sections.

The control section 1112 performs the operation control of the overall system by controlling each of the functioning sections to transmit and receive voice data, and to measure and display the current time. The control section 1112 includes a ROM having previously written programs, a CPU for reading and executing the programs written into the ROM, and a RAM used as a work area for the CPU and the like.

The time measuring section 1113 includes an integrated circuit containing an oscillating circuit, a register circuit, a counter circuit, and an interface circuit, and the piezoelectric vibrator 1. When a voltage is applied to the piezoelectric vibrator 1, the piezoelectric vibrating strip 5 (105, 205, 305, 405, 505, 605, 705, 805, 905) vibrates, and the vibrations are converted into an electric signal through the piezoelectric property provided by the crystal and is input as the electric signal to the oscillating circuit. The output from the oscillating circuit is binarized and measured by the register circuit and the counter circuit. Then, the signal is transmitted and received to and from the control section 1112 through the interface circuit to display the current time, the current date, the calendar information and the like on the display section 1115.

The communicating section 1114 has the function similar to that of the conventional cellular phone, and includes a radio section 1117, a voice processing section 1118, a switching section 1119, an amplifying section 1120, a voice input/output section 1121, a telephone number input section 1122, a ringtone generating section 1123, and a call control memory section 1124.

The radio section 1117 transmits and receives various types of data such as voice data to and from a base station through an antenna 1125. The voice processing section 1118 codes and decodes a voice signal input from the radio section 1117 or the amplifying section 1120. The amplifying section 1120 amplifies a signal input from the voice processing section 1118 or the voice input/output section 1121 to a predetermined level. The voice input/output section 1121 is formed of a speaker, a microphone or the like, and turns up the ringtone or received voice or collects the voice.

The ringtone generating section 1123 generates a ringtone in response to a call from the base station. The switching section 1119 switches the amplifying section 1120 connected to the voice processing section 1118 to the ringtone generating section 1120 only at the time of an incoming call such that the ringtone generated in the ringtone generating section 1123 is output to the voice input/output section 1121 through the amplifying section 1120.

The call control memory section 1124 stores a program associated with control of outgoing/incoming calls in communication. The telephone number input section 1122 includes numeric keys from zero to nine and other keys, for example, and these numeric keys or the like can be pressed to input the telephone number of a called party or the like.

When the voltage applied by the power source section 1111 to each of the functioning sections such as the control section 1112 falls below a predetermined value, the voltage detecting section 1116 detects the voltage drop and notifies the control section 1112 of the voltage drop. The predetermined voltage value is a previously set value as a minimum voltage required for stably operating the communicating section 1114, and is approximately 3 V, by way of example. Upon reception of the notification of the voltage drop from the voltage detecting section 1116, the control section 1112 prohibits the operations of the radio section 1117, the voice processing section 1118, the switching section 1119, and the ringtone generating section 1123. Especially, the stop of the operation of the radio section 1117 consuming large power is essential. In addition, the fact that the communicating section 1114 is disabled due to lack of remaining battery power is displayed on the display section 1115.

Specifically, the voltage detecting section 1116 and the control section 1112 can prohibit the operation of the communication section 1114 and display the fact on the display section 1115. This display may be performed with a text message, or by indicating x (small cross) on a telephone icon displayed in an upper portion on the display face of the display section 1115 as a more intuitive display.

A power source shutdown section 1126 capable of selectively shutting down the power source for the sections associated with the function of the communicating section 1114 can be provided to stop the function of the communicating section 1114 more reliably.

As described above, according to the portable information device 1110 of the present embodiment, the piezoelectric vibrator 1 is included which has a high strength and can suppress the CI value at a low level with a smaller size and higher performance, so that the portable information device 1110 can be provided with high reliability and high performance.

### (Radio Timepiece)

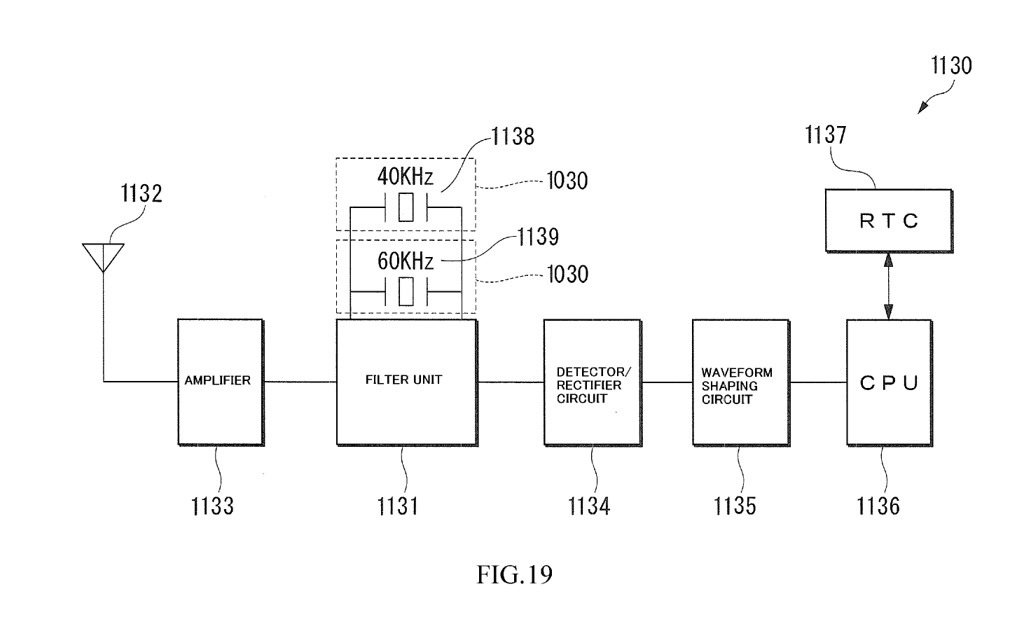

Next, an embodiment of a radio timepiece according to the present invention will be described with reference to FIG. 19.

FIG. 19 is a schematic diagram showing an embodiment of the radio timepiece.

As shown in FIG. 19, a radio timepiece 1130 of the present embodiment includes the piezoelectric vibrator 1 connected electrically to a filter section 1131, and is a timepiece which has the function of receiving standard radio waves including timepiece information, automatically correcting the information to an accurate time, and displaying the time.

In Japan, transmitters (transmitting stations) for transmitting the standard radio waves are present in Fukushima prefecture (for 40 kHz) and Saga prefecture (for 60 kHz) and transmit the standard radio waves. Long wave such as 40 kHz or 60 kHz has both the nature of propagating on the ground and the nature of propagating on the ionosphere and the ground while reflecting, so that it has a wide propagation range and thus the abovementioned two transmitters cover all over Japan.

The functional configuration of the radio timepiece 1130 will hereinafter be described in detail.

An antenna 1132 receives the standard long wave at 40 kHz or 60 kHz. The standard long wave is provided by amplitude-modulating the time information called a time code on a carrier wave at 40 kHz or 60 kHz. The received standard long wave is amplified by an amplifier 1133 and then filtered and synchronized by the filter section 1131 having a plurality of piezoelectric vibrators 1.

The piezoelectric vibrator 1 in the present embodiment includes crystal vibrator sections 1138 and 1139 having resonance frequencies at 40 kHz and 60 kHz identical to the abovementioned carrier frequencies.

The filtered signal at a predetermined frequency is then detected and demodulated by a detecting/rectifying circuit 1134.

Subsequently, the time code is taken through a waveform shaping circuit 1135 and is counted by a CPU 1136. The CPU 1136 reads the information such as the current year, total days, day of a week, time and the like. The read information is reflected in an RTC 1137 to display accurate time information.

Since the carrier wave is at 40 kHz or 60 kHz, the vibrator having the structure of the tuning fork type described above is preferable as the crystal vibrator sections 1138 and 1139.

While the above description is made with the example in Japan, the standard long wave has a different frequency in foreign countries. For example, the standard radio wave has a frequency of 77.5 kHz in Germany. Thus, to incorporate the radio timepiece 1130 which can be used overseas into a portable device, the piezoelectric vibrator 1 for a frequency different from that in Japan is necessary.

As described above, according to the radio timepiece 1130 of the present embodiment, the piezoelectric vibrator 1 is included which has a high strength and can suppress the CI value at a low level with a smaller size and higher performance, so that the radio timepiece 1130 can be provided with high reliability and high performance.

The present invention is not limited to the embodiments described above, and various modifications can be made to the embodiments described above without departing from the spirit or scope of the present invention.

For example, the piezoelectric vibrating strips 5, 105, 205, 305, 405, 505, 605, 705, 805, and 905 according to the present invention are employed in the piezoelectric vibrator 1 of the surface mounting type in the embodiments described above. However, the present invention is not limited thereto, and the piezoelectric vibrating strips 5, 105, 205, 305, 405, 505, 605, 705, 805, and 905 according to the present invention may be employed in a piezoelectric vibrator of a cylinder package type.

The embodiments have been described in the case where the single breaking portion 43 is formed in each of the pair of vibrating arm portions 24 to 924 and 25 and 925. However, the present invention is not limited thereto, and a plurality of breaking sections 43 may be formed in the longitudinal direction. In this case, the breaking portion 43 is formed in part of the portion where the first groove portion 41, 441, 641 and/or the second groove portion 42, 642 is formed in the pair of vibrating arm portions 24 to 924, 25 to 925. It is necessary to form the breaking portion at least between the nodes in the second warp mode. The formation of the breaking portion 43 between the nodes, that is, in the portion deformed in the second warp mode reduces the vibrations in the second warp mode to increase the R2 value.

When the plurality of breaking portions 43 are formed, the narrow groove portions 51, 53, 54, and 55 or the groove portion 52 may be formed in each of the breaking portions 43, or the narrow groove portions 51, 53, 54, and 55 or the groove portion 52 may be formed in some of the plurality of breaking portions 43.

The embodiments have been described in the case where the distance TL2 (see FIG. 5) between the center of the breaking portion 43 formed in the pair of vibrating arm portions 24 to 924 and 25 to 925 and the base end of the vibrating arm portions 24 to 924 and 25 to 925 is set to satisfy the expression (2). In other words, description has been made in the case where the breaking portion 43 is formed at the position where the maximum displacement is produced in the pair of vibrating arm portions 24 to 924 and 25 to 925 when the pair of vibrating arm portions 24 to 924 and 25 to 925 vibrates in the second warp mode, that is, at the position of the maximum amplitude portion P100 in FIG. 22 for the related art.

The present invention is not limited thereto, and it is only required that the breaking portion 43 should be formed between the vibrating node portion closer to the base end (for example, 2010a and 2011a in FIG. 22) when the pair of vibrating arm portions 24 to 924 and 25 and 925 vibrates in the second warp mode and the vibrating node portion closer to the leading end (for example, 2010b and 2011b in FIG. 22). More preferably, the position of the breaking portion 43 may be set such that the distance TL2 satisfies:

L/2TL≦TL2≦2 L/3 (6)

for the overall length L of the vibrating arm portions 24 to 294 and 25 to 925. The formation of the breaking portion 43 to satisfy the expression (6) can achieve the advantages similar to those in the first embodiment described above.

As apparent from the above, according to the present invention, the “deformation suppressing portion” for suppressing the higher-order vibrations is provided in the deformation area assuming that the vibrating arm portions vibrate in the higher-order warp mode. Thus, as compared with the case where the groove extending in the longitudinal direction with substantially the same width is formed in the vibrating arm portion, the R2 value can be increased by providing the “deformation suppressing portion” even with the generally same length of the groove. Thus, even when the length of the groove is increased for reducing the R value (CI value) of the piezoelectric vibrating strip, the relationship of R1<R2 can be maintained, which allows the vibration of the piezoelectric vibrating strip in the fundamental mode. For example, when the groove length TL1 is set as TL1/L≈0.6 for the length L of the vibrating arm, R1<R2 can be achieved. In addition, the present inventors have found that, when the “deformation suppressing portion” is formed at the position (for example, the middle position) where the largest deformation is produced in the second warp mode, R1<R2 can be maintained even when TL1/L≈0.68, that is, the vibrations can be made in the fundamental mode. When the breaking portion for the groove is provided as the deformation suppressing portion, the groove length is reduced by the provision of the breaking portion. However, only a small influence is exerted upon the electrolytic efficiency, and the benefit from the maintained relationship of R1<R2 is significantly important.

1. A piezoelectric vibrating strip in a comprising:
a base portion;
a plurality of parallel vibrating arms in a lateral width direction and having base ends coupled to the base portion and free ends extending away from the base portion;
a longitudinal groove in at least one of a main face or a back face of the vibrating arms and extending from proximate the base ends toward the free ends; and
a break portion dividing the longitudinal groove into a first groove portion and a second groove portion, the break portion suppressing warp deformation of the vibrating arms between a first vibrating node in proximity to the base end and a second vibrating node in proximity to the free end.

2. The piezoelectric vibrating strip of claim 1, wherein a ratio of a length of the vibrating arms L from the base portion to the free ends and a combined length of the first and second groove portions TL1, is such that TL1/L is about 0.60 to about 0.68.

3. The piezoelectric vibrating strip of claim 1, wherein the break portion resides proximate to a maximum amplitude portion of the vibrating arms when the vibrating arms oscillate between the first vibrating node and the second vibrating node.

4. The piezoelectric vibrating strip of claim 1, wherein the vibrating arms include a reduced width portion between the base ends and the free ends and the break portion resides in the reduced width portion.

5. The piezoelectric vibrating strip of claim 1, wherein the break portion includes a recess portion therein.

6. The piezoelectric vibrating strip of claim 5, wherein a ratio of a combined of the first groove and second groove portions is TL1 and a length from a center of the break portion to the base portion is TL2, is such that TL2/TL1 is about 0.50 to about 0.80.

7. The piezoelectric vibrating strip of claim 5, wherein the break portion includes two adjacent recess portions.

8. The piezoelectric vibrating strip of claim 7, wherein a width of the two adjacent recess portions is the same and the width of the two adjacent recess portions is less than one half of a width of each of the first and second groove portions.

9. The piezoelectric vibrating strip of claim 5, wherein the recess portion comprises a circular groove, a reduced width groove, or a slit in the main face or a back face of the vibrating arms.

10. The piezoelectric vibrating strip of claim 1 further comprising a third groove portion in the vibrating arms in proximity to the base ends.

11. The piezoelectric vibrating strip of claim 1, wherein the break portion comprises a narrow longitudinal groove that connects the first groove portion and the second groove portion.

12. The piezoelectric vibrating strip of claim 1, wherein the break portion comprises a narrow rib.

13. The piezoelectric vibrating strip of claim 1, wherein the base portion comprises a first base portion proximate to the base ends of the vibrating arms and a second base portion opposite the vibrating arms, where the first base portion has a smaller width than the second base portion in the lateral width direction.

14. The piezoelectric vibrating strip of claim 1 further comprising first and second side arms connected to the base portion in the lateral width direction and extending parallel to and on either side of the vibrating arms.

15. The piezoelectric vibrating strip of claim 14 further comprising first and second indentations in opposite sides of the base portion in the lateral width direction.

16. The piezoelectric vibrating strip of claim 1, wherein the break portion suppresses warp deformation of a second warp mode.

17. A piezoelectric vibrator including the piezoelectric vibrating strip according to claim 1.

18. An oscillator including the piezoelectric vibrator according to claim 17 electrically connected to an integrated circuit as an oscillator.

19. An electronic device including the piezoelectric vibrator according to claim 17 electrically connected to a time measuring section.

20. A radio timepiece including the piezoelectric vibrator according to claim 17 electrically connected to a filter section.
